(19) United States
(12) Patent Application Publication
(10) Pub. No.: US 2010/0129672 A1
(43) Pub. Date: May 27, 2010

(54) EASY-TO-CLEAN ARTICLE WITH STAINLESS STEEL SURFACE AND METHOD OF MAKING THE SAME

(75) Inventors: Lifei Hao, Shanghai (CN); Wenbin Liu, Shanghai (CN); Xiaodong Zhai, Shanghai (CN); Yan Wang, Shanghai (CN); Wayne W. Fan, St. Paul, MN (US); Rudolf J. Dams, Antwerp (BE)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/623,500

(22) Filed: Nov. 23, 2009

(30) Foreign Application Priority Data
Nov. 24, 2008 (CN) 200810181093.7

(51) Int. Cl. B32B 9/04; C23C 16/44

(52) U.S. Cl. 428/447; 427/255.14

(57) ABSTRACT

An easy-to-clean article with a stainless steel surface treated with a mixture of a fluorinated composition and a first compound. The fluorinated composition comprises a polyfluoropolyether group and a hydrolysable silane group. The first compound comprises an amino group, an epoxy group, or a mercapto group and a hydrolysable silane group. A method of treating a stainless steel surface with the mixture is also disclosed.

### CROSS REFERENCE TO RELATED APPLICATIONS

This applications claims priority to Chinese Patent Application No. 200810181093.7, filed Nov. 24, 2008, the disclosure of which is incorporated by reference herein in its entirety.

### BACKGROUND

Various techniques have been used to impart repellent properties to a substrate. For example, silane compounds or compositions having one or more fluorinated groups have been successfully used for rendering substrates such as glass and ceramics oil- and water-repellent. Such silane compounds or compositions have typically included one or more hydrolysable groups and at least one fluorinated alkyl group or fluorinated polyether group. Substrates that have been treated for oil and water repellency include glass, ceramics such as bathroom tile, enamel, metals, natural and man-made stone, polymers, and wood. However, the methods for treating these substrates typically have not been demonstrated to be successful for treating stainless steel. There continues to be a need for methods for imparting repellent properties to stainless steel surfaces and for stainless steel substrates having durable oil and water repellency.

### SUMMARY

Stainless steel surfaces are found on a variety of commonly used articles in the home and outdoors. For example, stainless steel is a popular material in kitchens and bathrooms and is used for faucets, shower heads, hand rails, range hoods, and other appliances. In another example, in automobiles, stainless steel is used for exterior parts such as wheel rims. Such stainless steel surfaces come in contact with a variety of oily and aqueous deposits such as cooking or automotive oil or grease, food, soap, dirt, sand, and minerals (e.g., lime). These deposits, which may be in the form of fingerprints, stains, or smudges, tend to show up easily on the surface and can be difficult to remove. Removing these deposits often requires aggressive scrubbing, frequently with cleaners or detergents, which may challenge the esthetic appearance of the surface. Easy-to-clean stainless steel surfaces which allow removal of oily and aqueous deposits without the need for aggressive scrubbing and which retain this property after repeated cleaning would, therefore, be advantageous. A method that can achieve this and articles made therefrom have now been found. The method can typically be carried out without expensive surface pretreatment of the stainless steel surface and typically, and advantageously, involves applying a chemical treatment in one step.

In one aspect, the present disclosure provides a method of making an easy-to-clean article having a stainless steel surface, the method comprising treating the stainless steel surface with a treatment composition comprising:

water;

acid;

organic solvent;

a fluorinated composition represented by formula:

Rf{X¹—[Si(Y)₃₋ₓ(R¹)ₓ]_{y}}_{z}; and

a first compound represented by formula:

L-[R²Si(Y)₃]ₖ
wherein:
   Rf is a polyfluoropolyether group;
   each Xⁱ is independently a divalent or trivalent organic linking group;
   each Y is independently halogen, alkoxy, acyloxy, polyalkyleneoxy, or aryloxy;
   R¹ is an alkyl group having up to 8 carbon atoms or a phenyl group;
   L is an amino group, a mercapto group, or an epoxy group;
   R² is alkylene optionally interrupted by at least one ether linkage;
   x is 0 or 1 or 2;
   y is 1 or 2;
   z is 1 or 2; and
   k is 1, with the proviso that when L is an amino group, k is 1 or 2.

In some embodiments of the method, the treatment composition further comprises at least one of (i.e., one or the other or both):

a second compound represented by formula:

(R³)_{b}Si(Y¹)_{4-b}; or

a third compound represented by formula:

M(Y¹)₄;
wherein
   each R³ is independently an alkyl group having up to 8 carbon atoms or a phenyl group, each of which may be substituted by halogen;
   each Y¹ is independently halogen, alkoxy, acyloxy, polyalkyleneoxy, or aryloxy;
   M is Si, Ti, or Zr, and
   b is 1 or 2.

In another aspect, the present disclosure provides an easy-to-clean article comprising a stainless steel surface, wherein the surface is treated according to any one of the above embodiments of the method disclosed herein.

In another aspect, the present disclosure provides an easy-to-clean article comprising a stainless steel surface, wherein at least a portion of the stainless steel surface is treated with a siloxane, the siloxane comprising a condensation product of at least a first compound and a fluorinated composition,

the first compound represented by formula:

L-[R²Si(Y)₃]ₖ; and

the fluorinated composition represented by formula:

Rf{X¹—[Si(Y)₃₋ₓ(R¹)ₓ]_{y}}ₓ;
wherein:
   Rf is a polyfluoropolyether group;
   each X¹ is independently a divalent or trivalent organic linking group;
   each Y is independently halogen, alkoxy, acyloxy, polyalkyleneoxy, or aryloxy;
   R¹ is an alkyl group having up to 8 carbon atoms or a phenyl group;
   L is an amino group, a mercapto group, or an epoxy group;
   R² is alkylene optionally interrupted by at least one ether linkage;
   x is 0 or 1 or 2;
   y is 1 or 2;
   z is 1 or 2; and
   k is 1, with the proviso that when L is an amino group, k is 1 or 2.

In some embodiments of the easy-to-clean article, the siloxane comprises a condensation product of the fluorinated composition, the first compound, and at least one of:

a second compound represented by formula:

(R³)_{b}Si(Y¹)_{4-b}; or

a third compound represented by formula:

M(Y¹)₄;
wherein
   each R³ is independently an alkyl group having up to 8 carbon atoms or a phenyl group, each of which may be substituted by halogen;
   each Y¹ is independently halogen, alkoxy, acyloxy, polyalkyleneoxy, or aryloxy;
   M is Si, Ti, or Zr, and
   b is 1 or 2.

As used herein, the terms “alkyl” and the prefix “alk” are inclusive of both straight chain and branched chain groups and of cyclic groups, e.g., cycloalkyl. Unless otherwise specified, these groups contain from 1 to 20 carbon atoms. In some embodiments, these groups have a total of up to 10 carbon atoms, up to 8 carbon atoms, up to 6 carbon atoms, or up to 4 carbon atoms. Cyclic groups can be monocyclic or polycyclic and preferably have from 3 to 10 ring carbon atoms.

The term “alkylene” is the divalent or trivalent form of the “alkyl” groups defined above.

Unless otherwise indicated, the term “halogen” refers to a halogen atom or one or more halogen atoms, including chlorine, bromine, iodine, and fluorine atoms.

The term “aryl” as used herein includes carbocyclic aromatic rings or ring systems optionally containing at least one heteroatom (i.e., O, N, or S). Examples of aryl groups include phenyl, naphthyl, biphenyl, and pyridinyl.

The term “arylene” is the divalent form of the “aryl” groups defined above.

“Arylalkylene” refers to an “alkylene” moiety to which an aryl group is attached.

The term “carbamate” refers to the group —O—C(O)—N(R′)— wherein R′ is as defined below.

The term “urea” refers to the group —N(R′)—C(O)—N(R′)— wherein each R′ is independently as defined below.

As used herein, “a,” “an,” “the,” “at least one,” and “one or more” are used interchangeably.

Also herein, the recitations of numerical ranges by endpoints include all numbers subsumed within that range, including the endpoints (e.g., 1 to 5 includes 1, 1.5, 2, 2.75, 3, 3.80, 4, 5, etc.). When the number is an integer, then only the whole numbers are included (e.g., 1, 2, 3, 4, 5, etc.).

The above summary is not intended to describe each disclosed embodiment or every implementation of the present disclosure. The description that follows more particularly exemplifies illustrative embodiments. In several places throughout the application, guidance is provided through lists of examples, which examples can be used individually and in various combinations. In each instance, the recited list serves only as a representative group and should not be interpreted as an exclusive list.

### DETAILED DESCRIPTION OF ILLUSTRATIVE EMBODIMENTS OF THE INVENTION

The present disclosure can overcome several challenges typically associated with coating stainless steel and provides easy-to-clean stainless steel articles and a method of making them using a chemical coating treatment. Due to its inert nature, coatings typically do not adhere well to stainless steel, which can result in poor durability of the coating. Stainless steel can be resistant to some types of surface treatments that are typically used to improve adhesion. While adhesion (e.g., of a coating) to some metals is improved by surface abrasion of the metal, stainless steel tends to work-harden under abrasive treatments. Chemical conversion coatings (e.g., chromate or phosphate coatings) can be used to improve the corrosion resistance and adhesion capabilities of some metals (e.g., galvanized steel, zinc, and aluminum) but are typically not used with stainless steel. Chromating solutions, which are acidic and function by dissolving some of the surface metal of the substrate to be chromated, are specifically designed for the metal to be treated. In contrast to a chromated steel surface, which may contain various levels of hexavalent chromium depending on the type of chromating solution, stainless steel generally forms a passivation layer of chromium(III) oxide on its surface. Therefore, the surfaces of stainless steel and treated metals such as chromated steel are quite different. Some surface modification techniques have been successfully used with stainless steel (see, e.g., WO 08/051,789 (David et al.)), but some of these techniques are expensive and time-consuming and may be difficult to carry out on larger stainless steel articles. Also, unlike some coatings and surface treatments, the articles and methods disclosed herein typically do not change the lustrous metallic appearance of the stainless steel.

Stainless steel useful for practicing the present disclosure includes a variety of grades. For example, the article can have a surface of austenitic, ferritic, or martensitic stainless steel containing at least about 10 (in some embodiments, 11, 12, 13, 14, 15, 16, 17, 18, 19, or 20) percent by weight of chromium. When the chromium content in the stainless steel at least about 10 percent by weight, the steel can generally readily be formed into a desired shape. Specific types of suitable stainless steels include 430, 304, and 316. Examples of articles having a stainless steel surface include kitchen and bathroom faucets, taps, handles, spouts, sinks, drains, hand rails, towel holders, curtain rods, dish washer panels, refrigerator panels, stove tops, stove, oven, and microwave panels, exhaust hoods, grills, automotive wheels or rims, and chemical reactors. Stainless steel articles that are treated according to the present disclosure include those having stainless steel surfaces in a wide range of thicknesses, depending on the application.

Treatment compositions useful for practicing the methods disclosed herein include a fluorinated composition comprising a polyfluoropolyether group and a hydrolysable silane group and a first compound comprising an amino group, an epoxy group, or a mercapto group and a hydrolysable silane group. Easy-to-clean articles according to the present disclosure include those having a stainless steel surface treated with the fluorinated composition and first compound themselves, those treated with a siloxane comprising a condensation product of at least the fluorinated composition and the first compound, and combinations thereof (e.g., partial condensates). Hydrolysis of the hydrolysable groups (e.g., alkoxy, acyloxy, or halogen) of the fluorinated compositions and first compounds typically generates silanol groups, which participate in condensation reactions to form fluorinated siloxanes, for example, according to the following reaction sequence:

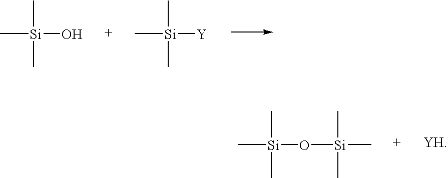

Typically, fluorinated compositions useful in practicing the present disclosure are represented by formula I-1:

Rf{X¹—[Si(Y)₃₋ₓ(R¹)ₓ]_{y}}_{z}; I-1.

In some embodiments, fluorinated compositions useful in practicing the present disclosure are represented by formula I:

Rf{Q-X—[R—Si(Y)₃₋ₓ(R¹)ₓ]_{y}}_{z} I.

In formulas I-1 and I, Rf is a polyfluoropolyether group, containing two or more in-chain oxygen atoms, which may be monovalent or divalent. Rf may be linear, branched, cyclic, or a combination thereof, and may be saturated or unsaturated. Rf is typically a perfluorinated group (i.e., all C—H bonds are replaced by C—F bonds). However, hydrogen or chlorine atoms may be present instead of fluorine atoms. Typically, not more than one atom of either hydrogen or chlorine is present for every two carbon atoms. In some embodiments, when hydrogen and/or chlorine are present, Rf includes at least one trifluoromethyl group. Compositions of formula I-1 and I, being oligomeric or polymeric in nature, typically exist as mixtures and are suitable for use as such.

In formula I-1, each X¹ is independently a divalent or trivalent organic linking group, which includes linear, branched, and cyclic structures. X¹ may be saturated or unsaturated and can contain 1 to 20 (1 to 15, or 1 to 10) carbon atoms and optionally one or more heteroatoms (e.g., O, N, or S). In some embodiments, X¹ contains up to four heteroatoms. The one or more heteroatoms can be combined into functional groups containing more than one heteroatom (e.g., amides, esters, and carbamates). In some embodiments, X¹ contains at least one functional group (e.g., up to 4 functional groups).

In formula I, Q is a bond, —C(O)—N(R′)—, —C(O)—O—, —SO₂N(R′)—, or —O—C(O)—N(R′)—. In some embodiments, Q is a bond, —C(O)—N(R′)—, or —C(O)—O—. In some embodiments, Q is —C(O)—N(R′)—. In any of these embodiments, R′ is hydrogen or alkyl having up to 4 carbon atoms (i.e., methyl, ethyl, propyl, or butyl). In some embodiments, R′ is hydrogen, methyl, or ethyl. In some embodiments, R′ is hydrogen or methyl.

In formula I, X is alkylene or arylalkylene. In some embodiments, X is alkylene. In some embodiments, X has up to 10, 8, 6, or 4 carbon atoms. X can be divalent or trivalent and is optionally at least one of interrupted or terminated by at least one functional group that is independently ether, thioether, sulfone, amine, ester, amide, carbamate, or urea. In some embodiments, X is optionally at least one of interrupted or terminated by at least one functional group that is independently ether, ester, carbamate, or amino. The phrase “interrupted by at least one functional group” refers to having alkylene or arylalkylene on either side of the functional group. Representative X groups that are interrupted by at least one functional group include —(CH₂)₁₋₁₀OC(O)N(R)—(CH₂)₁₋₁₀—, —(CH₂)₁₋₁₀O(CH₂)₁₋₁₀S(CH₂)₁₋₁₀—, and —(CH₂)₁₋₁₀OC(O)—(CH₂)₁₋₁₀—. The term “terminated by a functional group” refers to the functional group being connected to the R group in formula I. Representative X groups that are terminated by a functional group include —(CH₂)₁₋₁₀O(CH₂)₁₋₁₀O(CO)N(R′)—, —(CH₂)₁₋₁₀OC(O)(CH₂)₁₋₁₀N═, and

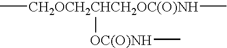

wherein R′ is hydrogen or C₁₋₄ alkyl.

In some embodiments, Q is —C(O)—N(R′)—, wherein X is alkylene having up to 8 carbon atoms, and wherein X is optionally at least one of interrupted or terminated by at least one functional group that is independently ether, ester, carbamate, or amino.

In formulas I-1 and I, each Y is independently halogen (i.e., fluoride, chloride, bromide, or iodide), alkoxy (i.e., —O-alkyl), acyloxy (i.e., —OC(O)alkyl), polyalkyleneoxy, or aryloxy (i.e., —O-aryl). The Y groups are generally capable of hydrolyzing, for example, in the presence of water under acidic conditions to produce groups capable of undergoing a condensation reaction, for example silanol groups. In these embodiments, alkyl (e.g., in alkoxy and acyloxy) is optionally substituted with one or more halogen atoms. In some embodiments, alkoxy and acyloxy have up to 8, 6, 4, 3, or 2 carbon atoms. In some embodiments, aryloxy has 6 to 12 (or 6 to 10) carbon atoms which may be unsubstituted or substituted by halogen, alkyl (e.g., having up to 4 carbon atoms), and haloalkyl. Polyalkyleneoxy is, for example, —O—(CH(CH₃)—CH₂O)_{q′—C}₁₋₄ alkyl, —O—(CH₂—CH₂O)_{q″}—C₁₋₄ alkyl, or a combination thereof (e.g., —O—(CH(CH₃)—CH₂O)_{q′}—(CH₂—CH₂O)_{q″}—C₁₋₄ alkyl with a ratio of q′ to q″ of 1:1 to 1:10), and q′, q″, or q′+q″ is 1 to 40 (in some embodiments, 2 to 10). In some embodiments, each Y is independently selected from the group consisting of halide, hydroxyl, alkoxy, aryloxy, and acyloxy. In some embodiments, each Y is independently selected from the group consisting of halide (e.g., chloride) and alkoxy having up to ten carbon atoms. In some embodiments, each Y is independently alkoxy having from 1 to 6 (e.g., 1 to 4) carbon atoms. In some embodiments, each Y is independently methoxy or ethoxy.

For some embodiments, including any one of the above embodiments of formulas I-1 and I, Rf comprises perfluorinated repeating units comprising at least one of —(CₙF₂ₙO)—, —(CF(Z)O)—, —(CF(Z)CₙF₂ₙO)—, or —(CₙF₂ₙCF(Z)O)—; wherein Z is a perfluoroalkyl group or a perfluoroalkoxy group, each of which is optionally interrupted by at least one ether linkage, and n is an integer from 1 to 12 (in some embodiments, 1 to 6, 1 to 4, or 1 to 3). In any of these formulas, Z can be linear, branched, or cyclic, and have 1 to 9 carbon atoms and 0 to 4 oxygen atoms. The perfluorinated repeating units may be arranged randomly, in blocks, or in an alternating sequence.

For some embodiments, including any one of the above embodiments, Rf is monovalent, and z is 1. For some of these embodiments, Rf is terminated with a group selected from the group consisting of CₙF₂ₙ₊₁—, CₙF₂ₙ₊₁O—, and X′CₙF₂ₙO— wherein X′ is a hydrogen or chlorine atom. For some of these embodiments, the terminal group is CₙF₂ₙ₊₁— or CₙF₂ₙ₊₁O—, wherein n is an integer from 1 to 6 or 1 to 3. For some of these embodiments, the approximate average structure of Rf is C₃F₇O(CF(CF₃)CF₂O)_{q}CF(CF₃)—, C₃F₇O(CF₂CF₂CF₂O)_{q}CF₂CF₂—, or CF₃O(C₂F₄O)_{q}CF₂—, wherein q has an average value of 3 to 50. In some embodiments, Rf is C₃F₇O(CF(CF₃)CF₂O)_{q}CF(CF₃)—, wherein q has an average value of 4 to 7.

For some embodiments, including any one of the above embodiments except where Rf is monovalent, Rf is divalent, and z is 2. For some of these embodiments, Rf is —CF₂O(CF₂O)ₘ(C₂F₄O)ₚCF₂—, —CF₂O(C₂F₄O)ₚCF₂—, —(CF₂)₃O(C₄F₈O)ₚ(CF₂)₃—, or —CF(CF₃)—(OCF₂CF(CF₃))ₚO—Rf′—O(CF(CF₃)CF₂O)ₚCF(CF₃)—, wherein Rf′ is a perfluoroalkylene group optionally interrupted by at least one ether or amine linkage, m is 1 to 50, and p is 3 to 40. For some of these embodiments, Rf′ is (CₙF₂ₙ), wherein n is 2 to 4. For some of these embodiments, Rf is —CF₂O(CF₂O)ₘ(C₂F₄O)ₚCF₂—, —CF₂O(C₂F₄O)ₚCF₂—, or —CF(CF₃)—(OCF₂CF(CF₃))ₚO—(CₙF₂ₙ)—O(CF(CF₃)CF₂O)ₚCF(CF₃)—, and wherein n is 2 to 4, and the average value of m+p or p+p or p is from about 4 to about 24.

The above described fluorinated compositions represented by formulas I-1 and I typically include a distribution of oligomers and/or polymers, so p and m may be non-integral. The above structures are approximate average structures where the approximate average is over this distribution. These distributions may also contain perfluoropolyethers with no silane groups or more than two silane groups. Typically, distributions containing less than about 10% by weight of compounds without silane groups can be used.

In formula I, R is a bond or alkylene having up to 4 carbon atoms (i.e., methylene, ethylene, propylene, or butylene). In some embodiments, R is a bond. In some embodiments, R is alkylene having up to 4 carbon atoms.

In formulas I-1 and I, R¹ is an alkyl group having up to 8 carbon atoms (e.g., methyl, ethyl, n-propyl, isopropyl, n-butyl, sec-butyl, tert-butyl, n-pentyl, isopentyl, neopentyl, n-hexyl, n-heptyl, or n-octyl) or a phenyl group. In some embodiments, R¹ is an alkyl group having up to 4 carbon atoms. In some embodiments, R¹ is methyl or ethyl.

In formula I-1 and I, x is 0, 1, or 2. In some embodiments, including any one of the above embodiments, x is 0 or 1 (in some embodiments, 0).

In formula I-1 and I, y is 1 or 2. In some embodiments, X is terminated by an amine or amide group, and y is 2. In some embodiments, y is 1.

In some embodiments, the number average molecular weight of the fluorinated composition is about 750 to about 6000, or about 800 to about 4000.

In some embodiments, including any one of the above embodiments Rf is —CF₂O(CF₂O)ₘ(C₂F₄O)ₚCF₂—, z is 2, y is 1, and X¹—Si(Y)₃₋ₓ(R¹)ₓ is C(O)NH(CH₂)₃Si(OCH₃)₃ or C(O)NH(CH₂)₃Si(OCH₂CH₃)₃. For some of these embodiments, m and p are each about 9 to 12.

The fluorinated compositions represented by formulas I-1 and I can be synthesized, for example, from a fluorinated carboxylic acid or salt thereof, an acid fluoride thereof, or a fluorinated carboxylic acid ester (e.g., Rf—[C(O)—OCH₃]_{z}) using a variety of conventional techniques. For example, a fluorinated methyl ester can be treated with an amine having formula NH₂—X—Si(Y)₃₋ₓ(R¹)ₓ according to the following reaction sequence.

Rf—[C(O)—OCH₃]_{z}+NH₂—X—Si(Y)₃₋ₓ(R¹)ₓ→Rf—[C(O)—NH—X—Si(Y)₃₋ₓ(R¹)ₓ]_{z}

In this sequence, Rf, X, Y, R¹, x, and z are as defined in any of the above embodiments. Some amines having formula NH₂—X—Si(Y)₃₋ₓ(R¹)ₓ are commercially available (e.g., (3-aminopropyl)trimethoxysilane and (3-aminopropyl)triethoxysilane). The reaction may be carried out, for example, at an elevated temperature (e.g., up to 80° C., 70° C., 60° C., or 50° C.), and may be carried out neat or in a suitable solvent. Conditions for carrying out these transformations are known in the art; see, e.g., U.S. Pat. Nos. 3,810,874 (Mitsch et al.) and 3,646,085 (Bartlett), the disclosures of which, relating to the preparation of fluorinated silanes, are incorporated herein by reference.

Some fluorinated methyl esters are commercially available (e.g., CH₃OC(O)CF₂(OCF₂CF₂)₉₋₁₀(OCF₂)₉₋₁₀CF₂C(O)OCH₃, a perfluoropolyether diester available from Solvay Solexis, Houston, Tex., available under the trade designation “FOMBLIN ZDEAL”). Others can be prepared, for example, through direct fluorination of a hydrocarbon polyether diester using techniques known in the art; see, e.g., methods disclosed in U.S. Pat. Nos. 5,578,278 (Fall et al.) and 5,658,962 (Moore et al.). In some embodiments, a fluorinated methyl ester is prepared by oligomerization of hexafluoropropylene oxide (HFPO) and functionalization of the resulting perfluoropolyether carbonyl fluoride according to the methods described in U.S. Pat. No. 4,647,413 (Savu), the disclosure of which is incorporated herein by reference.

Fluorinated compositions represented by formulas I-1 and I can also be prepared, for example, by reaction of a carboxylic acid ester (e.g., Rf—[C(O)—OCH₃]_{z}) with an amino alcohol having formula NH₂—X″—OH (e.g., ethanolamine) to prepare fluorinated hydroxyl compound Rf—[(CO)NHX″OH]_{z} as shown in the following reaction sequence, wherein Rf is as defined in any of the above embodiments, and X″ is a precursor to X, wherein X is interrupted by at least one ether, ester, or carbamate group.

Rf—[C(O)—OCH₃]_{z}+NH₂—X″—OH→Rf—[C(O)—NH—X″—OH]_{z}→Rf—[C(O)—NH—X—Si(Y)₃₋ₓ(R¹)ₓ]_{z}

The conditions for the reaction with NH₂—X—Si(Y)₃₋ₓ(R¹)ₓ, described above, can be used for the reaction with NH₂—X″—OH. The fluorinated hydroxyl compound can then be treated with, for example, a haloalkyl silane (e.g., chloropropyltrimethoxysilane) or an isocyanatoalkyl silane (e.g., 3-isocyanatopropyltriethoxysilane). The reaction with a haloalkyl silane can be carried out, for example, by first treating the fluorinated hydroxyl compound with a base (e.g., sodium methoxide or sodium tert-butoxide) in a suitable solvent (e.g., methanol), optionally at an elevated temperature (e.g., up to the reflux temperature of the solvent), followed by heating (e.g., at up to 100° C., 80° C., or 70° C.) the resulting alkoxide with the haloalkyl silane. The reaction of a fluorinated hydroxyl compound represented by formula Rf—[C(O)—NH—X″—OH]_{z} with an isocyanatoalkyl silane can be carried out, for example, in a suitable solvent (e.g., methyl ethyl ketone), optionally at an elevated temperature (e.g., the reflux temperature of the solvent), and optionally in the presence of a catalyst (e.g., stannous octanoate).

Fluorinated compositions represented by formulas I-1 and I can also be prepared, for example, by reducing an ester of formula Rf—[C(O)—OCH₃]_{z} or a carboxylic acid of formula Rf—[C(O)—OH]_{z} using conventional methods (e.g., hydride, such as sodium borohydride, reduction) to a fluorinated hydroxyl compound of formula Rf—[CH₂OH]_{z} as shown in the following reaction sequence, wherein Rf, X, Y, R¹, x, and z are as defined in any of the above embodiments, and X is interrupted by at least one ether, ester, or carbamate group.

Rf—[C(O)—OCH₃]_{z}→Rf—[CH₂OH]_{z}→Rf—[X—Si(Y)₃₋ₓ(R¹)ₓ]_{z}

The fluorinated hydroxyl compound of formula Rf—[CH₂OH]_{z} can then be converted, for example, to a silane by reaction with a haloalkyl silane or isocyanatoalkyl silane using the techniques described above. Some useful fluorinated hydroxyl compounds are commercially available (e.g., HOCH₂CF₂(OCF₂CF₂)₉₋₁₀(OCF₂)₉₋₁₀CF₂CH₂OH, a perfluoropolyether diol available from Solvay Solexis available under the trade designation “FOMBLIN ZDOL”).

Fluorinated hydroxyl compounds can also be treated, for example, with allyl halides (e.g., allyl chloride, allyl bromide, or allyl iodide) under the conditions described above for the reaction of fluorinated hydroxyl compounds with haloalkyl silanes. The resulting allyl-substituted compounds can be treated with, for example, a commercially available, or readily synthesized, mercaptosilane of the formula HS—X—Si(Y)₃₋ₓ(R¹)ₓ, wherein X, Y, R¹, and x can be defined as in any of the above embodiments, under free radical conditions. Useful free radical initiators include hydrogen peroxide, potassium persulfate, t-butyl hydroperoxide, benzoyl peroxide, t-butyl perbenzoate, cumene hydroperoxide, 2,2′-azobis(2-methylbutyronitrile), azobis(isobutyronitrile) (AIBN), and free radical photoinitiators such as those described by K.K. Dietliker in Chemistry & Technology of UV & EB Formulation for Coatings, Inks & Paints, Volume 3, pages 276-298, SITA Technology Ltd., London (1991). Conditions for carrying out this transformation are known in the art; see, e.g., U.S. Pat. No. 7,294,731 (Flynn et al.), the disclosure of which, relating to the preparation of fluorinated silanes, is incorporated herein by reference.

Fluorinated hydroxyl compounds can also be treated, for example, with acryloyl halides, esters, anhydrides or acrylic acid to produce fluorinated acrylate esters, which can then be treated, for example, with amines having formula NH_{(3-y)}—[R—Si(Y)₃₋ₓ(R¹)ₓ]_{y}, wherein R, Y, R¹, x, and y can be defined as in any of the above embodiments, according to the methods described in U.S. Pat. Appl. No. 2008/0220264 (Iyer et al.), the disclosure of which, relating to the preparation of fluorinated silanes, is incorporated herein by reference. The reaction between fluorinated acrylate esters and amines are optionally carried out in dry solvent and optionally in the presence of 0.05 percent to 2 percent by weight catalyst (e.g., a base such as 1,4-dihydropyridines, methyl diphenylphosphane, methyl di-p-tolylphosphane, 2-allyl-N-alkyl imidazolines, tetra-t-butylammonium hydroxide, DBU (1,8-diazabicyclo[5.4.0]undec-7-ene), tetramethylguanidine, DBN (1,5-diazabicyclo[4.3.0]non-5-ene), potassium methoxide, sodium methoxide, or sodium hydroxide). Conveniently, progress of the reaction can be determined using infrared spectroscopy. Fluorinated acrylate esters can also be treated with mercaptosilanes represented by formula HS—X—Si(Y)₃₋ₓ(R¹)ₓ, under similar conditions.

Treatment compositions useful for practicing the present disclosure include a first compound represented by formula II:

L-[R²Si(Y)₃]ₖ II.

In formula II, L is an amino group (e.g., primary or secondary amino group), a mercapto group (i.e., HS—), or an epoxy group (i.e.,

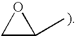

In some embodiments, L is an epoxy group. In formula II, k is typically 1, but when L is an amino group, k is 1 or 2.

In formula II, R² is alkylene (e.g., having up to 8, 6, or 4 carbon atoms) optionally interrupted by at least one ether linkage. In some embodiments, R² is interrupted by one ether linkage.

In formula II, each Y is independently as defined in any of the embodiments for formula I above.

Useful first compounds represented by formula II include 3-glycidoxypropyltrimethoxysilane, available, for example, from Dow Corning Corporation, Midland, Mich., under the trade designation “DOW CORNING Z-6040 SILANE”; bis(trimethoxysilylpropyl)amine available, for example, from Gelest, Morrisville, Pa.; (3-aminopropyl)trimethoxysilane, (3-aminopropyl)triethoxysilane), (3-mercaptopropyl)trimethoxysilane, and (3-mercaptopropyl)triethoxysilane available, for example, from Sigma-Aldrich, St. Louis, Mo. In some embodiments, the first compound is 3-glycidoxypropyltrimethoxysilane.

In some embodiments, treatment compositions useful for practicing the present disclosure include a second compound represented by formula III:

(R³)_{b}Si(Y¹)_{4-b} III.

Easy-to-clean articles according to some embodiments of the present disclosure include those having a stainless steel surface treated with the fluorinated composition and the first and second compounds themselves, those treated with a siloxane comprising a condensation product of at least the fluorinated composition, the first compound, and the second compound represented by formula III, and combinations thereof (e.g., partial condensates).

In formula III, each R³ is independently an alkyl group having up to 8 (in some embodiments, up to 6 or 4) carbon atoms or a phenyl group, each of which may be substituted by halogen (i.e., fluoride, chloride, bromide, or iodide). In some embodiments, each R³ is independently an alkyl group having up to 8 (in some embodiments, up to 6 or 4) carbon atoms and optionally substituted by halogen. In formula III, b is 1 or 2. In some embodiments, b is 1.

In formula III, each Y¹ is independently halogen, alkoxy, acyloxy, polyalkyleneoxy, or aryloxy. In these embodiments, alkyl (e.g., in alkoxy and acyloxy) is optionally interrupted with one or more halogen atoms. In some embodiments, alkoxy and acyloxy have up to 8, 6, 4, 3, or 2 carbon atoms. In some embodiments, aryloxy has 6 to 12 (or 6 to 10) carbon atoms which may be unsubstituted or substituted by halogen, alkyl (e.g., having up to 4 carbon atoms), and haloalkyl. Polyalkyleneoxy is, for example, —O—(CH(CH₃)—CH₂O)_{q′}—C₁₋₄ alkyl, —O—(CH₂—CH₂O)_{q″}—C₁₋₄ alkyl, or a combination thereof (e.g., —O—(CH(CH₃)—CH₂O)_{q′}—(CH₂—CH₂O)_{q″}—C₁₋₄ alkyl with a ratio of q′ to q″ of 1:1 to 1:10), and q′, q″, or q′+q″ is 1 to 40 (in some embodiments, 2 to 10). In some embodiments, each Y¹ is independently selected from the group consisting of halide, hydroxyl, alkoxy, aryloxy, and acyloxy. In some embodiments, each Y¹ is independently selected from the group consisting of halide (e.g., chloride) and alkoxy having up to ten carbon atoms. In some embodiments, each Y¹ is independently alkoxy having from 1 to 6 (e.g., 1 to 4) carbon atoms. In some embodiments, each Y¹ is independently methoxy or ethoxy.

Useful second compounds represented by formula III include methyltriethoxysilane, dimethyldiethoxysilane, methyltrichlorosilane, and 3-chloropropyltriethoxysilane.

In some embodiments, treatment compositions useful for practicing the present disclosure use a third compound represented by formula IV:

M(Y¹)₄ IV.

Easy-to-clean articles according to some embodiments of the present disclosure include those having a stainless steel surface treated with the fluorinated compositions, the first and third compound themselves, those treated with a siloxane comprising a condensation product of at least the fluorinated composition, the first compound, and the third compound represented by formula IV, and combinations thereof (e.g., partial condensates).

In formula IV, M is Si, Ti, or Zr. In some embodiments, M is Si. In formula IV, Y¹ is as defined above in any of the embodiments described for formula III. Useful third compounds of formula IV include tetramethoxysilane (i.e., tetramethyl orthosilicate), tetraethoxysilane (i.e., tetraethyl orthosilicate), tetramethyl orthotitanate, tetraethyl orthotitanate, tetraisopropyl orthotitanate, tetraethylzirconate, tetraisopropylzirconate, and tetrapropylzirconate. In some embodiments, M(Y¹)₄ is Si(O-alkyl)₄.

A treatment composition useful for practicing the present disclosure typically includes from at least 0.01, 0.015, 0.02, 0.025, 0.03, 0.035, 0.04, 0.045, 0.05, 0.055, 0.06, 0.065, 0.07, 0.075, 0.08, 0.085, 0.09, 0.095, 0.1, 0.15, 0.2, 0.25, or 0.5 percent by weight, up to 1, 1.5, or 2 percent by weight of at least one fluorinated composition represented by formula I or I-1, based on the total weight of the treatment composition. For example, the amount of a fluorinated composition represented by formula I or I-1 in a treatment composition may be in a range of from 0.01 to 2, 0.01 to 1, 0.05 to 2, 0.05 to 1, or from 0.1 to 1 percent by weight, based on the total weight of the treatment composition. Lower or higher amounts of the fluorinated composition may also be used, and may be desirable for some applications.

A treatment composition useful for practicing the present disclosure typically includes from at least 0.025, 0.03, 0.035, 0.04, 0.045, 0.05, 0.055, 0.06, 0.065, 0.07, 0.075, 0.08, 0.085, 0.09, 0.095, 0.1, 0.15, 0.2, 0.25, 0.5, or 1 percent by weight, up to 2, 3, 4, or 5 percent by weight of at least one first compound represented by formula II, based on the total weight of the treatment composition. For example, the amount of a first compound represented by formula II in a treatment composition may be in a range of from 0.025 to 5, 0.1 to 5, 0.05 to 3, 0.1 to 3, or from 0.1 to 2 percent by weight, based on the total weight of the treatment composition. In some embodiments, the weight ratio of the first compound to the fluorinated composition in the treatment composition is at least 2 to 1 (in some embodiments, at least 2.2:1, 2.5:1, 2.8:1, 3:1, 3.5:1, or 4:1). Typically, treatment compositions wherein the ratio of the first compound to the fluorinated composition is at least 2:1 have at least one of better easy-to-clean performance or more durable easy-to-clean performance than treatment compositions wherein this ratio is less than 2:1.

In some embodiments, treatment compositions useful for practicing the present disclosure contain a second compound represented by formula III. In some embodiments, the fluorinated composition is present in the treatment composition in a range from 0.01 percent to 2 percent by weight, based on the total weight of the treatment composition, the second compound is present in the treatment composition in a range from 0.05 percent to 10 percent by weight, based on the total weight of the treatment composition, and the first compound is present in the treatment composition in a range from 0.1 percent to 5 percent by weight, based on the total weight of the treatment composition. In some embodiments of easy-to-clean articles according to the present disclosure, the siloxane treating the surface of the easy-to-article comprises a condensation product of the fluorinated composition relative to the first and second compounds combined in a weight ratio ranging from 1:5 to 1:120.

In some embodiments, treatment compositions useful for practicing the present disclosure contain a third compound represented by formula IV. In some embodiments, treatment compositions useful for practicing the present disclosure contain less than 0.1 percent by weight of the third compound, based on the total weight of the composition. In some embodiments, the third compound is present relative to the first and second compounds combined in a weight ratio not greater than 1:1. In some of these embodiments, the third compound is present relative to the first and second compounds combined in a weight ratio ranging from 1:1 to 1:5. When this ratio is about 1:1.8 to 1:3.5, typically, improved durability is observed. In some embodiments of treatment compositions comprising a third compound of formula IV, the ratio of the third compound to the fluorinated composition may be, for example, in a range from 3:1 to 12:1, or in a range from 6:1 to 9:1.

In some embodiments, treatment compositions useful for practicing the present disclosure comprise compounds (e.g., the first compound and at least one of the second compound or the third compound) and the fluorinated composition in a ratio of at least 10:1, 15:1, or at least 20:1.

Treatment compositions useful for practicing the present disclosure comprise acid. In some embodiments, the acid comprises at least one of (i.e., comprises one or more of) acetic acid, citric acid, formic acid, triflic acid, perfluorobutyric acid, sulfuric acid, or hydrochloric acid. In some embodiments, the acid is hydrochloric acid. Stronger acids typically effect the hydrolysis of silane groups at a lower temperature than weaker acids and are therefore sometimes desirable. The acid may be present in the treatment composition in a range, for example, from about 0.004, 0.007, 0.01, or 0.015 percent by weight to about 1, 1.5, 2, 2.5, or 3 percent by weight, based on the total weight of the treatment composition. In some embodiments, the acid is present in an amount up to 0.5, 0.4, 0.3, 0.2, or 0.1 percent by weight based on the total weight of the treatment composition. In some embodiments, when the amount of acid exceeds about 0.05 percent by weight, the substrate has a spotty appearance. In some embodiments, the acid is hydrochloric acid and is present in the treatment composition in a range from 0.004 to 0.05 percent by weight, based on the total weight of the treatment composition.

Treatment compositions useful for practicing the present disclosure comprise water. Water may be useful in the treatment composition, for example, to alter the distribution the fluorinated composition in the treatment composition after it is introduced to the surface of the stainless steel article. In some embodiments, the water is present in the treatment composition in a range from 0.01 percent to 10 percent (in some embodiments, 0.05 to 10, 0.1 to 10, 0.15 to 10, 1 to 10, or 1 to 8 percent) by weight, based on the total weight of the treatment composition. Water may be added to the treatment compositions separately or may be added as part of an aqueous acidic solution (e.g., concentrated hydrochloric acid is 37% by weight of the acid in water).

Typically, treatment compositions useful in practicing the present disclosure include organic solvent. As used herein, the term “organic solvent” includes a single organic solvent and a mixture of two or more organic solvents. Useful organic solvents are typically capable of dissolving at least about 0.01 percent by weight of a fluorinated composition represented by formula I or I-1 in the presence of at least 0.01 (e.g., 0.1) percent by weight water and at least 0.004 (e.g., 0.01) percent by weight acid.

Suitable organic solvents include aliphatic alcohols (e.g., methanol, ethanol, and isopropanol); ketones (e.g., acetone and methyl ethyl ketone); esters (e.g., ethyl acetate and methyl formate); ethers (e.g., diethyl ether, diisopropyl ether, methyl t-butyl ether and dipropyleneglycol monomethylether (DPM)); hydrocarbons such as alkanes (e.g., heptane, decane, and paraffinic solvents); and fluorinated solvents such as partially or fully fluorinated hydrocarbons (e.g., perfluorohexane, perfluorooctane, and pentafluorobutane) and hydrofluoroethers (e.g., methyl perfluorobutyl ether and ethyl perfluorobutyl ether). In some embodiments, the organic solvent is methanol, ethanol, isopropanol, or a mixture thereof. In some embodiments, the organic solvent is ethanol.

The ratio of the solvents, water, acid, fluorinated compositions, first compounds, and other components (e.g., second and third compounds) may be chosen to provide a homogeneous mixture.

Treatment compositions useful in practicing the present disclosure may be applied to stainless steel articles either shortly after their preparation (e.g., up to one hour), or after standing at room temperature for a period of time (e.g., more than 1 hour, 3 to 8 hours, several days, or several weeks). Hydrolysis and condensation of the fluorinated compositions and the first, second, and third compounds may be more likely to occur after compositions are exposed to time and temperature. Typically treatment compositions disclosed herein are applied within several (e.g., up to 8, 6, 5, 3, 2, or 1) hours after they are prepared and are not heated prior to their application.

Treatment compositions useful for practicing the present disclosure may be prepared from a concentrate (e.g., a concentrated solution of a fluorinated composition represented by formula I or I-1 and/or a first compound in organic solvent). The concentrate may be stable for several weeks (e.g., at least one, two, or three months) and may comprise the fluorinated composition in an amount of at least 10, 20, 25, 30, or at least 40 percent by weight, based on the total weight of the concentrate. Concentrates may be diluted shortly before use, for example, with water, organic solvent, acid, and optionally additional fluorinated composition or first, second, or third compounds. In some embodiments, the concentrate comprises the fluorinated composition and the first compound in the same weight ratio desired in the final, diluted treatment composition. In some of these embodiments, the concentrate comprises the fluorinated composition and the first, second, and optionally third compound in the same weight ratio desired in the final, diluted treatment composition.

In some embodiments, the surface of the stainless steel article to be treated may be cleaned before treatment. It is typically desirable to remove foreign materials such as dust, oil, grease, and other contamination. Cleaning may be carried out, for example, with a solution of sodium hydroxide (e.g., 2, 5, or 10 percent by weight aqueous sodium hydroxide), with water, with an organic solvent (e.g., a ketone such as acetone or an alcohol such as ethanol), or with a combination thereof. The cleaning may be carried out at room temperature or at an elevated temperature (e.g., in a range from about 50° C. to about 100° C.). Techniques for cleaning the surface of the stainless steel article include wiping, rinsing, and sonicating. After cleaning, the surface of the stainless steel article may be dried, for example, under a stream of air or nitrogen or at an elevated temperature.

A wide variety methods can be used to treat a stainless steel surface with a treatment composition disclosed herein (e.g., brushing, spraying, dipping, rolling, spreading, or chemical vapor deposition). A stainless steel surface can typically be treated with a treatment composition at room temperature (typically, about 15° C. to about 30° C. or about 20° C. to about 25° C.). Or the treatment composition can be applied to surfaces that are preheated (e.g., at a temperature of 60° C. to 150° C.). Following application, the treated article can be dried and cured at ambient or elevated temperature (e.g., at 40° C. to 300° C., 50° C. to 150° C., or 60° C. to 120° C.) and for a time sufficient to dry. In some embodiments, repellent and durable surface treatments according to the present disclosure can be obtained upon treating an article and drying at ambient temperature. In some embodiments, methods disclosed herein further comprise a polishing step to remove excess material. Easy-to-clean articles prepared according to the present disclosure wherein the treatment composition is dried typically no longer have organic solvent or water present on the surface.

In some embodiments, including any one of the above embodiments, the method of making an easy-to-clean article having a stainless steel surface further comprises subjecting at least the surface to an elevated temperature after treating the stainless steel surface with the treatment composition.

In some embodiments, including any one of the above embodiments of the treated easy-to-clean article, the thickness of the treatment is at least about 10, 20, 30, or 50 nanometers, up to about 100, 150, or 200 nanometers. Thin coatings made according to the methods disclosed herein typically and advantageously are transparent and do not change the luster of the stainless steel surface.

The easy-to-clean performance of the articles and methods disclosed herein is typically measured by evaluating contact angles of at least one of water or hydrocarbon (e.g., hexadecane) on the treated surface. Receding contact angle and contact angle hysteresis (i.e., the difference between the advancing and receding contact angle values) are believed to be indicative of easy-to-clean performance. In this application, contact angles are measured at room temperature (e.g., about 25° C. to 30° C.) using equipment obtained from Kruss GmbH, Hamburg, Germany, and are usually measured three times to obtain an average measurement. In some embodiments of the methods and articles disclosed herein, the treated stainless steel surface has an initial receding contact angle versus water of at least 80 (in some embodiments, at least 82, 84, 86, 88, or 90) degrees. In some embodiments of the methods and articles disclosed herein, the treated stainless steel surface has an initial contact angle hysteresis versus water of up to 30 (in some embodiments, up to 28, 26, 24, 22, or 20) degrees. In some embodiments of the methods and articles disclosed herein, the treated stainless steel surface has an initial receding contact angle versus hexadecane of at least 50 (in some embodiments, at least 52, 54, 56, 58, or 60) degrees. In some embodiments of the methods and articles disclosed herein, the treated stainless steel surface has an initial contact angle hysteresis versus hexadecane of up to 30 (in some embodiments, up to 28, 26, 24, 22, or 20) degrees. In these embodiments, “initial” refers to contact angles measured for the treated surface about 24 hours after treating the surface and before any abrading or wiping of the treated surface. Stainless steel surfaces treated according to the present disclosure typically have at least one of a higher receding contact angle or a lower contact angle hysteresis versus at least one of water or hexadecane than an equivalent surface treated with an acidic solution of a 6:1 ratio of tetraethyl orthosilicate to (CH₃O)₃Si(CH₂)₃NHCOCF₂(OCF₂CF₂)₉₋₁₀(OCF₂)₉₋₁₀OCF₂CONH(CH₂)₃Si(OCH₃)₃, described in U.S. Pat. No. 6,716,534 (Moore et al.). The term “equivalent surface” refers to a stainless steel surface that is similar to or the same (e.g., in grade, surface preparation, and surface composition) as a stainless steel surface disclosed herein before it is treated according to the present disclosure. In the present application, contact angles are determined after cleaning stainless steel plates of grade 304 having dimensions of 8 cm by 5 cm by 0.05 cm (obtained from Shanghai Yongfeng International Trading Co., Ltd., China) with neutral cleaner (obtained from 3M China, Limited, Shanghai, China) followed by placing the plates in acetone in a sonicating bath for 20 minutes and drying with compressed air. After combining at least the fluorinated composition, the first compound, acid, water, and organic solvent, the treatment composition is allowed stand for 1 hour at room temperature and then sprayed onto cleaned and dried stainless steel plates under compressed air (2 kg/cm²). The plate is then dried in an oven at 120° C. for 30 minutes and allowed to stand for 24 hours before evaluation by contact angle.

Stainless steel surfaces treated according to the present disclosure typically provide durable easy-to-clean performance (i.e., the easy-to-clean performance is maintained after cleaning the surface several times). In this application, durability is measured by measuring contact angles versus water of a treated stainless steel plate before and after being subjected to abrasion. Abrasion is carried out by fixing the stainless steel plate on an abrasion tester (obtained from BYK-Gardener GmbH, Geretsried, Germany, under the trade designation “BYK-GARDENER ABRASION TESTER”) and scrubbing for 5000 cycles with a microfiber cloth obtained from 3M Company, St. Paul, Minn. under the trade designation “3M HIGH PERFORMANCE CLOTH”, which is water-wet. The scrubbing cycles are carried out with 1 kg force. In some embodiments of the methods and articles disclosed herein, the treated stainless steel surface has a receding contact angle versus water of at least 65 (in some embodiments, at least 68, 70, 72, or 75) degrees after 5000 scrub cycles under 1 kilogram force with a water-wet cloth. In some embodiments of the methods and articles disclosed herein, the treated stainless steel surface has a contact angle hysteresis versus water of up to 35 (in some embodiments, up to 33, 31, 28, or 25) degrees after 5000 scrub cycles under 1 kilogram force with a water-wet cloth. In some embodiments of the methods and articles disclosed herein, the treated stainless steel surface has a receding contact angle versus hexadecane of at least 20 (in some embodiments, at least 22, 25, 28, 30, 32, or 35) degrees after 5000 scrub cycles under 1 kilogram force with a water-wet cloth. In some embodiments of the methods and articles disclosed herein, the treated stainless steel surface has a contact angle hysteresis versus hexadecane of up to 30 (in some embodiments, up to 28, 26, 24, 22, or 20) degrees after 5000 scrub cycles under 1 kilogram force with a water-wet cloth. In some embodiments, including any of the above embodiments in which scrub cycles are carried out with a water-wet cloth, the cloth is a microfiber cloth. In some of these embodiments, the cloth is a polyester-polyamide microfiber cloth. Stainless steel surfaces treated according to the present disclosure typically have, after abrasion, at least one of a higher receding contact angle or a lower contact angle hysteresis versus at least one of water or hexadecane than an equivalent surface treated with an acidic solution of a 6:1 ratio of tetraethyl orthosilicate to (CH₃O)₃Si(CH₂)₃NHCOCF₂(OCF₂CF₂)₉₋₁₀(OCF₂)₉₋₁₀OCF₂CONH(CH₂)₃Si(OCH₃)₃, described in U.S. Pat. No. 6,716,534 (Moore et al.). Unexpectedly durable performance is typically observed when the weight ratio of the first compound to the fluorinated composition in the treatment composition is at least 2 to 1.

Objects and advantages of this disclosure are further illustrated by the following examples, but the particular materials and amounts thereof recited in these examples, as well as other conditions and details, should not be construed to unduly limit the invention.

### EXAMPLES

### Preparation of (CH₃O)₃Si(CH₂)₃NHCOCF₂(OCF₂CF₂)₉₋₁₀(OCF₂)₉₋₁₀OCF₂CONH(CH₂)₃Si(OCH₃)₃

CH₃OC(O)CF₂(OCF₂CF₂)₉₋₁₀(OCF₂)₉₋₁₀OCF₂C(O)OCH₃ (a perfluoropolyether diester obtained from Solvay Solexis, Houston, Tex., available under the trade designation “FOMBLIN ZDEAL”) (50 grams (g)) was added to an oven-dried 100-mL round bottom flask under a nitrogen atmosphere and stirred rapidly at room temperature using a magnetic stirrer. 3-Aminopropyltrimethoxysilane (9.1 g) (obtained from Momentive Performance Materials, Albany, N.Y., available under the trade designation “SILQUEST A-1110”) was added to the flask in one portion. Initially the mixture was two-phase, and as the reagents mixed the mixture became cloudy. A reaction exotherm to a temperature of 30° C. was observed, and then the reaction gradually cooled to room temperature and became a slightly hazy light yellow liquid. The reaction was monitored by gas chromatography (GC) to observe excess 3-aminopropyltrimethoxysilane and fourier transform infrared spectroscopy (FTIR) to observe unreacted ester functional groups and was found to be complete within 30 minutes after the addition of 3-aminopropyltrimethoxysilane.

The reaction product was stirred rapidly, and the pressure in the flask was reduced to 1 mmHg (133 Pa) gradually to minimize bumping. Methanol was distilled from the flask over a period of two hours, and 57.5 g of (CH₃O)₃Si(CH₂)₃NHCOCF₂(OCF₂CF₂)₉₋₁₀(OCF₂)₉₋₁₀OCF₂CONH(CH₂)₃Si(OCH₃)₃ was recovered from the flask.

### Preparation of F(CF(CF₃)CF₂O)ₙCF(CF₃)—CONHCH₂CH₂OCOCH₂—CH₂—N—[(CH₂)₃—Si(OCH₃)₃]₂

A 100-mL 3-necked round bottom flask was equipped with magnetic stir bar, nitrogen gas inlet and reflux condenser and was charged with F(CF(CF₃)CF₂O)ₙCF(CF₃)—CONHCH₂CH₂OCOCH═CH₂ (HFPO-AEA) (10 grams, 0.007 moles, n=7) under nitrogen atmosphere. HFPO-AEA was prepared as described in paragraphs 100 to 103 of U.S. 2005/0249942 (Coggio et al.), the disclosure of which paragraphs are incorporated herein by reference. Bis(trimethoxysilylpropyl)amine (2.43 grams, 0.00714 mole, obtained from Gelest, Morrisville, Pa.) was added dropwise to the flask over a period of 15 minutes. The reaction was exothermic, and was stirred for 30 minutes at room temperature and subsequently heated at 55° C. for 12 hours to provide F(CF(CF₃)CF₂O)ₙCF(CF₃)—CONHCH₂CH₂OCOCH₂—CH₂—N—[(CH₂)₃—Si(OCH₃)₃]₂.

### Preparation of F(CF(CF₃)CF₂O)ₙCF(CF₃)—CONHCH₂CH₂CH₂Si(OCH₃)₃

F(CF(CF₃)CF₂O)ₙCF(CF₃)—CONHCH₂CH₂CH₂Si(OCH₃)₃ (n=7) was prepared according to the method described in Example 1 of U.S. Pat. No. 3,646,085, the disclosure of which example is incorporated herein by reference.

### Preparation of Mixture 1

(CH₃O)₃Si(CH₂)₃NHCOCF₂(OCF₂CF₂)₉₋₁₀(OCF₂)₉₋₁₀OCF₂CONH(CH₂)₃Si(OCH₃)₃ disilane (100 grams, 0.036 mole), prepared as described above, was combined with 600 grams tetraethyl orthosilicate (TEOS, obtained from Sigma-Aldrich, St. Louis, Mo.), and 300 grams ethanol to provide a solution of 60 wt. % TEOS, 30 wt. % ethanol, and 10 wt. % of the disilane.

### Preparations 1 to 21

For Preparations 1 to 13, Mixture 1 was combined with 3-glycidoxypropyltrimethoxysilane (GPTS) (obtained from Dow Corning Corporation, Midland, Mich., under the trade designation “DOW CORNING Z-6040 SILANE”) and methyltriethoxysilane (MTS) (obtained from TCI Development Co., Ltd., Shanghai, China) in ethanol in the amounts indicated in Table 1, below, to form a solution. Water was then added in the amount shown in Table 1, below, and the resulting mixture was shaken. Concentrated hydrochloric acid (HCl) was then added in the amount shown in Table 1, below, and the resulting mixture was shaken again. For Preparations 15 to 21, Mixture 1 was combined with methyltriethoxysilane (MTS, obtained from Sigma-Aldrich, Bornem, Belgium), 3-glycidoxypropyltrimethoxysilane (GPTS, obtained from Sigma-Aldrich, Bornem, Belgium), and ethanol in the amounts indicated in Table 1, below, to make a solution. Concentrated hydrochloric acid (HCl, 37 wt. %), in the amount indicated in Table 1, below, was added and the resulting mixture was shaken again to provide a solution. Although no additional water was added, each Preparation 15-20 contained 0.063 weight percent water, and Preparation 21 contained 0.63 weight percent water, which was added as part of the concentrated hydrochloric acid.

TABLE 1

| Preparation | MTS | GPTS | Mixture 1 | HCl | Water | Ethanol |
|---|---|---|---|---|---|---|
| (Prep.) | wt. % | wt. % | wt. % | wt. % | wt. % | wt. % |
| Prep. 1 | 0.51 | 0.2 | 1 | 0.0125 | 6.25 | 92 |
| Prep. 2 | 0.77 | 0.2 | 1 | 0.0125 | 6.25 | 92 |
| Prep. 3 | 0.51 | 0.68 | 1 | 0.0125 | 6.25 | 91.5 |
| Prep. 4 | 0.77 | 0.68 | 1 | 0.0125 | 6.25 | 91 |
| Prep. 5 | 1.02 | 0.68 | 1 | 0.0125 | 6.25 | 91 |
| Prep. 6 | 1.2 | 0.79 | 1 | 0.0125 | 6.25 | 91 |
| Prep. 7 | 1.35 | 0.91 | 1 | 0.0125 | 6.25 | 90.5 |
| Prep. 8 | 1.02 | 0.68 | 1 | 0.05 | 6.25 | 91 |
| Prep. 9 | 0 | 0.68 | 1 | 0.0125 | 6.25 | 90.8 |
| Prep. 10 | 1 | 0.7 | 1 | 0.0125 | 0.01 | 97 |
| Prep. 11 | 1.02 | 0.68 | 1 | 0.1 | 6.25 | 91 |
| Prep. 12 | 1.02 | 0.68 | 1 | 0.15 | 6.25 | 91 |
| Prep. 13 | 1.02 | 0 | 1 | 0.0125 | 6.25 | 90.5 |
| Prep. 14 | 0 | 0 | 1 | 0.0125 | | 98.9 |
| Prep. 15 | 0.5 | 0.5 | 1 | 0.1 | | 97.9 |
| Prep. 16 | 1.2 | 1.2 | 1 | 0.1 | | 96.5 |
| Prep. 17 | 1.2 | 0.6 | 1 | 0.1 | | 97.1 |
| Prep. 18 | 0 | 1.2 | 1 | 0.1 | | 97.7 |
| Prep. 19 | 0.5 | 0 | 1 | 0.1 | | 98.4 |
| Prep. 20 | 0 | 0 | 1 | 0.1 | | 98.9 |
| Prep. 21 | 0 | 0 | 1 | 1 | | 98 |

### Preparations 22 to 26

Preparations 22 to 26 were made according to the method of Preparations 1 to 13 except Compounds 1, 2, and 2a, shown in Table 2, below, instead of GPTS and MTS were combined with 1 wt. % Mixture 1. For each of Preparations 22 to 26, 0.0125 wt. % of concentrated HCl was used. 3-Chloropropyltriethoxysilane (CPTS) was obtained from TCI (Shanghai) Development Co. Ltd., under the trade designation “JH-130”. Dimethyldiethoxysilane (DMDS) was obtained from TCI (Shanghai) Development Co. Ltd. (3-Mercaptopropyl)triethoxysilane (MPTS) was obtained from TCI (Shanghai) Development Co. Ltd.

TABLE 2

| Preparation | Compound 1 | Compound 2 | Compound 2a | Water | Ethanol |
|---|---|---|---|---|---|
| (Prep.) | (wt. %) | (wt. %) | (wt. %) | wt. % | Wt. % |
| Prep. 22 | GPTS (0.5) | CPTS (0.5) | DMDS (0.5) | 6.25 | 91 |
| Prep. 23 | MPTS (1) | DMDS (10) | Not used | 6.25 | 82 |
| Prep. 24 | GPTS (0.1) | DMDS (3) | Not used | 6.25 | 90 |
| Prep. 25 | GPTS (5) | MTS (0.05) | Not used | 6.25 | 88 |
| Prep. 26 | GPTS (0.25) | CPTS (1.5) | Not used | 10 | 87 |

### Preparation 27

(CH₃O)₃Si(CH₂)₃NHCOCF₂(OCF₂CF₂)₉₋₁₀(OCF₂)₉₋₁₀OCF₂CONH(CH₂)₃Si(OCH₃)₃ disilane (0.1 gram), prepared as described above, was combined with 1.2 gram methyltriethoxysilane (MTS, obtained from Sigma-Aldrich, Bornem, Belgium), 3-glycidoxypropyltrimethoxysilane (GPTS, obtained from Sigma-Aldrich), and ethanol (97.4 grams) to make a solution. 0.1 gram concentrated hydrochloric acid (HCl, 37 wt. %) was added, and the resulting mixture was shaken again to provide a solution of 0.1 wt. % disilane, 1.2 wt. % MTS, 1.2 wt. % GPTS, 0.1 wt. % HCl, and 97.4 wt. % ethanol.

### Examples 1 to 15

### Comparative Examples A to C

For Examples 1 to 15, Comparative Examples A and B, and control example I (i.e., no treatment), stainless steel plates of grade 304 having dimensions of 8 cm by 5 cm by 0.05 cm (Shanghai Yongfeng International Trading Co., Ltd., China) were used. Each plate was washed with neutral cleaner (obtained from 3M China Limited, Shanghai, China) and then placed in acetone in a sonicating bath for 20 minutes. Each plate was then dried with compressed air. Preparations 1 to 14 were made as described above and allowed to stand for 1 hour at room temperature. Each of the preparations was sprayed onto separate, cleaned and dried stainless steel plates under compressed air (2 kg/cm²). For Examples 1 to 15 and Comparative Example A, the plate was then placed in an oven and dried at 120° C. for 30 minutes. For Comparative Example B, the plate was placed in an oven and dried at 60° C. for 30 minutes. The samples were allowed to stand for 24 hours before evaluation by contact angle.

### Examples 1 to 15, Comparative Examples A and B, and control example I were evaluated for contact angle versus water and hexadecane, and oil repellency before and after abrasion.

Abrasion: A stainless steel plate was fixed on an abrasion tester (obtained from BYK-Gardener GmbH, Geretsried, Germany, under the trade designation “BYK-GARDENER ABRASION TESTER”) and scrubbed for 5000 cycles with a microfiber cloth obtained from 3M Company, St. Paul, Minn. under the trade designation “3M HIGH PERFORMANCE CLOTH”, which was wet with water. The scrubbing cycles were carried out with 1 kg force.

Contact angles versus water and hexadecane were measured for Examples 1 to 15, Comparative Examples A and B, and Control Example I with an instrument obtained from Kruss GmbH, Hamburg, Germany, under the trade designation “DSA 100E”. The mean values of 3 measurements and are reported in degrees in Tables 3 and 4 (below).

TABLE 3

| | | Contact angles (°) | | Contact angles (°) | |
|---|---|---|---|---|---|
| | | versus water | | versus water | |
| | | Before abrasion | | After abrasion | |
| Example | Preparation | static | receding | static | receding |
| Ex. 1 | 1 | 114 | 97 | 94 | 46 |
| Ex. 2 | 2 | 118 | 104 | 104 | 69 |
| Ex. 3 | 3 | 121 | 100 | 109 | 75 |
| Ex. 4 | 4 | 115 | 98 | 107 | 76 |
| Ex. 5 | 5 | 117 | 100 | 107 | 80 |
| Ex. 6 | 6 | 112 | 105 | 98 | 75 |
| Ex. 7 | 7 | 112 | 103 | | |
| Ex. 8 | 8 | 114 | 103 | 105 | 96 |
| Ex. 9 | 9 | 114 | 102 | 99 | 75 |
| Ex. 10 | 10 | 107 | 78 | 98 | 69 |
| Ex. 11 | 22 | 110 | 89 | 106 | 80 |
| Ex. 12 | 23 | 110 | 95 | 104 | 75 |
| Ex. 13 | 24 | 103 | 70 | 98 | 56 |
| Ex. 14 | 25 | 105 | 88 | 100 | 78 |
| Ex. 15 | 26 | 110 | 86 | 95 | 62 |
| Comp. Ex. A | 13 | 110 | 95 | 96 | 69 |
| Comp. Ex. B | 14 | 123 | 76 | 92 | 45 |
| Cont. Ex. I | none | 92 | 40 | | |

TABLE 4

| | | Contact angles (°) | | Contact angles (°) | |
|---|---|---|---|---|---|
| | | versus hexadecane | | versus hexadecane | |
| | | Before abrasion | | After abrasion | |
| Example | Preparation | static | receding | static | receding |
| Ex. 5 | 5 | 67 | 50 | 53 | 33 |
| Ex. 8 | 8 | 70 | 61 | 59 | 47 |
| Ex. 9 | 9 | 65 | 62 | 44 | 30 |
| Comp. Ex. A | 13 | 63 | 57 | 49 | 23 |
| Comp. Ex. B | 14 | 67 | 27 | 44 | 9 |
| Cont. Ex. I | none | 6 | 12 | | |

Stainless steel plates were also treated with Preparations 11 and 12 according to the method of Examples 1 to 15 to prepare Examples 16 and 17, respectively. Example 16 had a course surface with some spots, and Example 17 had many spots on the surface. Examples 5 to 16, Comparative Examples A and B, and Control Example I were tested for Oil Repellency. A stainless steel plate was immersed in soy oil (obtained from COFCO Limited, China under the trade designation “FULINMEN”). The plate was then removed from the oil and the time was observed. The flow of oil from the plate was observed from the time the plate was pulled from the oil until the time when the final drop of oil dropped from the plate, and the total time was recorded. The results are given in Table 5, below.

TABLE 5

| | | Oil Repellency | Oil Repellency |
|---|---|---|---|
| | | Oil flow time, | Oil flow time, |
| | | seconds | seconds |
| Example | Preparation | Before Abrasion | After Abrasion |
| Ex. 5 | 5 | 27 | 87 |
| Ex. 6 | 6 | 20 | 91 |
| Ex. 7 | 7 | 23 | 90 |
| Ex. 8 | 8 | 24 | 60 |
| Ex. 9 | 9 | 24 | 208 |
| Ex. 10 | 10 | 45 | 205 |
| Ex. 11 | 22 | 34 | 63 |
| Ex. 12 | 23 | 26 | 84 |
| Ex. 13 | 24 | 42 | 195 |
| Ex. 14 | 25 | 19 | 75 |
| Ex. 15 | 26 | 40 | 219 |
| Ex. 16 | 11 | 33 | 160 |
| Comp. Ex. A | 13 | 40 | >240 |
| Comp. Ex. B | 14 | 46 | >300 |
| Cont. Ex. I | none | >300 | |

### Examples 18 to 22 and Comparative Examples C to E and Contact Angle Measurements

For Examples 18 to 22, Comparative Examples C to E, and control example II (i.e., substrate with no treatment), stainless steel plates of grade 316 having dimensions of 10 cm by 10 cm by 0.05 cm (obtained from Ideal Standard, Wittlich, Germany) were used. Each plate was washed with 5 wt. % aqueous sodium hydroxide at 70° C., rinsed with water followed by acetone, and then dried under a stream of nitrogen. Preparations 15 to 21 were made as described above and allowed to stand for 1 hour at room temperature. Each of the preparations was sprayed onto separate, cleaned and dried stainless steel plates. The pressure during spraying was about 2 bar (2×10⁵ Pa), the flow about 40 mL/minute, and the add-on about 150 mL/m². Each plate was allowed to dry at room temperature for 24 hours before evaluation by contact angle.

Examples 18 to 22, Comparative Examples C to E, and control example II were evaluated for contact angle versus water and hexadecane and cleanability before and after being subjected to abrasion.

Abrasion: An abrasion test was carried out by fixing a stainless steel plate on an Erichsen cleaning machine (obtained from DCI, Belgium) applying cleaner (obtained from Procter and Gamble, Cincinnati, Ohio, under the trade designation “MR PROPER”) and wiping with a microfiber cloth (available from 3M Company, St. Paul, Minn. under the trade designation “3M HIGH PERFORMANCE CLOTH”) for 4000 cycles.

Contact angles: Static contact angles versus water and hexadecane were measured with an instrument obtained from Kruss GmbH, Hamburg, Germany, under the trade designation “DSA 100”. The mean values of 3 measurements and are reported in degrees in Table 6 (below).

TABLE 6

| | | | Contact Angle (°) | | Contact Angle (°) | |
|---|---|---|---|---|---|---|
| | | Cleanability | Before abrasion | | After abrasion | |
| Example | Preparation | Rating (0-10) | water | hexadecane | water | hexadecane |
| Ex. 18 | Prep. 15 | 4 | 104 | 70 | 84 | 57 |
| Ex. 19 | Prep. 16 | 5 | 104 | 70 | 85 | 55 |
| Ex. 20 | Prep. 17 | 4 | 102 | 68 | 84 | 56 |
| Ex. 21 | Prep. 18 | 4 | 103 | 67 | 82 | 52 |
| Ex. 22 | Prep. 27 | 4 | 105 | 69 | 85 | 57 |
| Comp. Ex. C | Prep. 19 | 3 | 103 | 67 | 70 | 22 |
| Comp. Ex. D | Prep. 20 | 3 | 102 | 65 | 77 | 20 |
| Comp. Ex. E | Prep. 21 | 2 | 105 | 67 | 75 | 22 |
| Cont. Ex. II | none | 0 | 62 | <20 | 58 | <20 |

The cleanability of the fittings of Examples 18 to 22, Comparative Examples C to E, and control example II was carried out by applying mineral water (available from Tonissteiner, Germany). The water was sprayed at 0.5 bar (5×10⁴ Pa) at room temperature until the substrate was completely covered. The substrate was placed in an oven for two hours at 70° C., removed, and allowed to cool. Salt deposits were present on the substrates, which were then cleaned with a dry paper wipe. The cleaning results were evaluated visually and rated on a scale of 0 (impossible to remove the deposits) to 10 (no visual marks left after 3 wipes). The results are shown in Table 6 (above).

### Preparation 28

F(CF(CF₃)CF₂O)ₙCF(CF₃)—CONHCH₂CH₂OCOCH₂—CH₂—N—[(CH₂)₃—Si(OCH₃)₃]₂ disilane (1.0 gram, 0.59 mmol, n=7), prepared as described above, was combined with 2.0 grams methyltriethoxysilane (MTS, obtained from Sigma-Aldrich, Milwaukee, Wis.), 2.0 grams 3-glycidoxypropyltrimethoxysilane (GPTS, obtained from Dow Corning Corporation under the trade designation “DOW CORNING Z-6040 SILANE”) in ethanol (495 grams) to make a solution. 5.0 grams concentrated hydrochloric acid (HCl, 37% by weight) was added, and the resulting mixture was shaken again to provide a solution of 0.2 wt. % disilane, 0.4% wt. % MTS, 0.4% wt. % GPTS, 1 wt. % HCl, and 98 wt. % ethanol.

### Preparation 29

Preparation 29 was made according to the method of Preparation 28 except F(CF(CF₃)CF₂O)ₙCF(CF₃)—CONHCH₂CH₂CH₂Si(OCH₃)₃ silane was used instead of F(CF(CF₃)CF₂O)ₙCF(CF₃)—CONHCH₂CH₂OCOCH₂—CH₂—N—[(CH₂)₃—Si(OCH₃)₃]₂ disilane to provide a solution of 0.2 wt. % silane, 0.4% wt. % MTS, 0.4% wt. % GPTS, 1 wt. % HCl, and 98 wt. % ethanol.

### Preparation 30

Preparation 30 was made according to the method of Preparation 28 except no MTS or GPTS was used. A solution of 0.2 wt. % disilane, 1 wt. % HCl, and 98.8 wt. % ethanol was provided.

### Preparation 31

Preparation 31 was made according to the method of Preparation 28 except F(CF(CF₃)CF₂O)ₙCF(CF₃)—CONHCH₂CH₂CH₂Si(OCH₃)₃ silane was used instead of F(CF(CF₃)CF₂O)ₙCF(CF₃)—CONHCH₂CH₂OCOCH₂—CH₂—N—[(CH₂)₃—Si(OCH₃)₃]₂ disilane, and no MTS or GPTS was used. A solution of 0.2 wt. % silane, 1 wt. % HCl, and 98.8 wt. % ethanol was provided.

### Examples 23 and 24 and Comparative Examples F and G

For Examples 23 and 24 and Comparative Examples F and G, the procedure of preparing and treating stainless steel plates in Examples 1 to 15 and Comparative Examples A to C was followed except using the Preparations shown in Table 7, below.

Examples 23 and 24 and Comparative Examples F and G were evaluated for contact angle versus water and hexadecane (static, advancing, and receding) before and after being subjected to abrasion.

Abrasion: A stainless steel plate was fixed on an abrasion tester (obtained from Paul N. Gardener Company, Inc., Pompano Beach, Fla., under the trade designation “WASHABILITY & WEAR TESTER”) and scrubbed for 2000 cycles with a microfiber cloth obtained from 3M Company, St. Paul, Minn. under the trade designation “3M HIGH PERFORMANCE CLOTH”, which was wet with water. The scrubbing cycles were carried out with 1 kg force.

Contact angles: Contact angles versus water and hexadecane were measured with an instrument obtained from Kruss GmbH, Hamburg, Germany, under the trade designation “G120 MK1/G140 MK1”. The mean values of 3 measurements and are reported in degrees in Table 7, below.

TABLE 7

| | | Contact angles (°) | | | | | | Contact angles (°) | | | | | |
|---|---|---|---|---|---|---|---|---|---|---|---|---|---|
| | | Before abrasion | | | | | | After abrasion | | | | | |
| | | | | | Versus | | | | | | Versus | | |
| | | Versus water | | | hexadecane | | | Versus water | | | hexadecane | | |
| Ex. | Prep. | Sta | Adv | Rec | Sta | Adv | Rec | Sta | Adv | Rec | Sta | Adv | Rec |
| 23 | 28 | 109 | 107 | 100 | 72 | 68 | 67 | 99 | 102 | 79 | 64 | 63 | 39 |
| 24 | 29 | 114 | 122 | 103 | 79 | 76 | 65 | 101 | 102 | 73 | 62 | 66 | 36 |
| CE F | 30 | 105 | 103 | 100 | 75 | 74 | 67 | 92 | 88 | 61 | 47 | 47 | 16 |
| CE G | 31 | 107 | 120 | 102 | 77 | 65 | 66 | 95 | 89 | 55 | 46 | 43 | 18 |

The complete disclosures of the patents, patent documents and publications cited herein are incorporated by reference in their entirety as if each were individually incorporated. In case of conflict, the present specification, including definitions, shall control. Various modifications and alterations to this invention will become apparent to those skilled in the art without departing from the scope and spirit of this invention. Illustrative embodiments and examples are provided as examples only and are not intended to limit the scope of the present invention. The scope of the invention is limited only by the claims set forth as follows.

What is claimed is:

1. A method of making an easy-to-clean article having a stainless steel surface, the method comprising treating the stainless steel surface with a treatment composition comprising:
water;
acid;
organic solvent;
a fluorinated composition represented by formula:
Rf{X¹—[Si(Y)₃₋ₓ(R¹)ₓ]_{y}}_{z}; and
a first compound represented by formula:
L-[R²Si(Y)₃]ₖ
wherein:
Rf is a polyfluoropolyether group;
each X¹ is independently a divalent or trivalent organic linking group;
each Y is independently halogen, alkoxy, acyloxy, polyalkyleneoxy, or aryloxy;
R¹ is an alkyl group having up to 8 carbon atoms or a phenyl group;
L is an amino group, a mercapto group, or an epoxy group;
R² is alkylene optionally interrupted by at least one ether linkage;
x is 0 or 1 or 2;
y is 1 or 2;
z is 1 or 2; and
k is 1, with the proviso that when L is an amino group, k is 1 or 2.

2. The method according to claim 1, wherein Rf comprises perfluorinated repeating units comprising at least one of —(CₙF₂ₙO)—, —(CF(Z)O)—, —(CF(Z)CₙF₂ₙO)—, or —(CₙF₂ₙCF(Z)O)—; and wherein Z is a perfluoroalkyl group or a perfluoroalkoxy group, each of which is optionally interrupted by at least one ether linkage, and n is an integer from 1 to 12.

3. The method according to claim 2, wherein z is 2, and Rf is —CF₂O(CF₂O)ₘ(C₂F₄O)ₚCF₂—, —CF₂O(C₂F₄O)ₚCF₂—, —(CF₂)₃O(C₄F₈O)ₚ(CF₂)₃—, or —CF(CF₃)—(OCF₂CF(CF₃))ₚO—Rf′—O(CF(CF₃)CF₂O)ₚCF(CF₃)—, and wherein Rf′ is a perfluoroalkylene group optionally interrupted by at least one ether or amine linkage, m is 1 to 50, and p is 3 to 40.

4. The method according to claim 1, wherein Rf is C₃F₇O(CF(CF₃)CF₂O)_{q}CF(CF₃)—, C₃F₇O(CF₂CF₂CF₂O)_{q}CF₂CF₂—, or CF₃O(C₂F₄O)_{q}CF₂—, wherein q has an average value of 3 to 50, and wherein z is 1.

5. The method according to claim 1, wherein X¹ is Q-X—R, Q is a bond, —C(O)—N(R′)—, —C(O)—O—, —SO₂N(R′)—, or —O—C(O)—N(R′)—, wherein R′ is hydrogen or alkyl having up to 4 carbon atoms; X is alkylene or arylalkylene, each of which is optionally at least one of interrupted or terminated by at least one functional group that is independently ether, thioether, sulfone, amine, ester, amide, carbamate, or urea; and R is a bond or alkylene having up to 4 carbon atoms.

6. The method according to claim 5, wherein Q is —C(O)—N(R′)—, wherein X is alkylene having up to 8 carbon atoms, and wherein X is optionally at least one of interrupted or terminated by at least one functional group that is independently ether, ester, carbamate, or amino.

7. The method according to claim 1, wherein the weight ratio of the first compound to the fluorinated composition in the treatment composition is at least 2 to 1.

8. The method according to claim 1, wherein the treatment composition further comprises at least one of:
a second compound represented by formula:
(R³)_{b}Si(Y¹)_{4-b}; or
a third compound represented by formula:
M(Y¹)₄;
wherein
each R³ is independently an alkyl group having up to 8 carbon atoms or a phenyl group, each of which may be substituted by halogen;
each Y¹ is independently halogen, alkoxy, acyloxy, polyalkyleneoxy, or aryloxy;
M is Si, Ti, or Zr, and
b is 1 or 2.

9. The method according to claim 8, wherein the third compound is present relative to the first and second compounds combined in a weight ratio not greater than 1:1.

10. The method according to claim 1, wherein the acid is hydrochloric acid, and wherein the acid is present in the treatment composition in a range from 0.004 to 0.05 percent by weight, based on the total weight of the composition.

11. An easy-to-clean article comprising a stainless steel surface, wherein the surface is treated by the method according to claim 1.

12. An easy-to-clean article comprising a stainless steel surface, wherein at least a portion of the stainless steel surface is treated with a siloxane, the siloxane comprising a condensation product of at least a first compound and a fluorinated composition,
the first compound represented by formula:
L-[R²Si(Y)₃]ₖ; and
the fluorinated composition represented by formula:
Rf{X¹—[Si(Y)₃₋ₓ(R¹)ₓ]_{y}}_{z};
wherein:
Rf is a polyfluoropolyether group;
each X¹ is independently a divalent or trivalent organic linking group;
each Y is independently halogen, alkoxy, acyloxy, polyalkyleneoxy, or aryloxy;
R¹ is an alkyl group having up to 8 carbon atoms or a phenyl group;
L is an amino group, a mercapto group, or an epoxy group;
R² is alkylene optionally interrupted by at least one ether linkage;
x is 0 or 1 or 2;
y is 1 or 2;
z is 1 or 2; and
k is 1, with the proviso that when L is an amino group, k is 1 or 2.

13. The easy-to-clean article according to claim 12, wherein Rf comprises perfluorinated repeating units comprising at least one of —(CₙF₂ₙO)—, —(CF(Z)O)—, —(CF(Z)CₙF₂ₙO)—, or —(CₙF₂ₙCF(Z)O)—; and wherein Z is a perfluoroalkyl group or a perfluoroalkoxy group, each of which is optionally interrupted by at least one ether linkage, and n is an integer from 1 to 12.

14. The easy-to-clean article according to claim 13, wherein z is 2, and Rf is —CF₂O(CF₂O)ₘ(C₂F₄O)ₚCF₂—, —CF₂O(C₂F₄O)ₚCF₂—, —(CF₂)₃O(C₄F₈O)ₚ(CF₂)₃—, or —CF(CF₃)—(OCF₂CF(CF₃))ₚO—Rf′—O(CF(CF₃)CF₂O)ₚCF(CF₃)—, and wherein Rf′ is a perfluoroalkylene group optionally interrupted in chain by at least one ether or amine linkage, m is 1 to 50, and p is 3 to 40.

15. The easy-to-clean article according to claim 12, wherein Rf is C₃F₇O(CF(CF₃)CF₂O)_{q}CF(CF₃)—, C₃F₇O(CF₂CF₂CF₂O)_{q}CF₂CF₂—, or CF₃O(C₂F₄O)_{q}CF₂—, wherein q has an average value of 3 to 50, and wherein z is 1.

16. The easy-to-clean article according to claim 12, wherein X¹ is Q-X—R, wherein Q is a bond, —C(O)—N(R′)—, —C(O)—O—, —SO₂N(R′)—, or —O—C(O)—N(R′)—, wherein R′ is hydrogen or alkyl having up to 4 carbon atoms; X is alkylene or arylalkylene, each of which is optionally at least one of interrupted or terminated by at least one functional group that is independently ether, thioether, sulfone, amine, ester, amide, carbamate, or urea; and R is a bond or alkylene having up to 4 carbon atoms.

17. The easy-to-clean article according to claim 16, wherein Q is —C(O)—N(R′)—, wherein X is alkylene having up to 8 carbon atoms, and wherein X is optionally at least one of interrupted or terminated by at least one functional group that is independently ether, ester, carbamate, or amino.

18. The easy-to-clean article according to claim 12, wherein the siloxane comprises a condensation product of the first compound and the fluorinated composition in a weight ratio of at least 2 to 1.

19. The easy-to-clean article according to claim 12, wherein the siloxane comprises a condensation product of the fluorinated composition, the first compound, and at least one of:
a second compound represented by formula:
(R³)_{b}Si(Y¹)_{4-b}; or
a third compound represented by formula:
M(Y¹)₄;
wherein
each R³ is independently an alkyl group having up to 8 carbon atoms or a phenyl group, each of which may be substituted by halogen;
each Y¹ is independently halogen, alkoxy, acyloxy, polyalkyleneoxy, or aryloxy;
M is Si, Ti, or Zr, and
b is 1 or 2.

20. The easy-to-clean article according to claim 19, wherein the siloxane comprises a condensation product of the third compound relative to the first and second compounds combined in a weight ratio not greater than 1:1.

21. The easy-to-clean article according to claim 12, wherein the treated stainless steel surface has a receding contact angle versus water of at least 70 degrees after 5000 scrub cycles under 1 kilogram force with a water-wet microfiber cloth.
